(19) United States
(12) Patent Application Publication
(10) Pub. No.: US 2002/0081840 A1
(43) Pub. Date: Jun. 27, 2002

(54) Method of manufacturing a semiconductor device including dual-damascene process

(75) Inventor: Akira Matumoto, Tokyo (JP)

Correspondence Address: YOUNG & THOMPSON, 745 SOUTH 23RD STREET 2ND FLOOR, ARLINGTON, VA, 22202

(73) Assignee: Nec Corporation, Tokyo (JP)

(21) Appl. No.: 10/026,683

(22) Filed: Dec. 27, 2001

(30) Foreign Application Priority Data
Dec. 27, 2000 (JP) 2000-399585

(51) Int. Cl. H01L 21/4763; H01L 21/44

(52) U.S. Cl. 438/672; 438/624; 438/637; 438/638

(57) ABSTRACT

Provided is a semiconductor device manufacturing process capable of forming an interconnection trench and a via hole highly precisely in a dual-damascene process. In the semiconductor device manufacturing method in accordance with the present invention, first, second, and third insulating layers are formed over a lower interconnection, a part of the third insulating layer is selectively etched to form an upper trench, which exposes an upper surface of the second insulating layer; a via hole, of which diameter is smaller than the width of the upper trench, is formed in the second and first insulating layers, and the second insulating layer is selectively etched to form a lower trench whose width is nearly identical to the width of the upper trench, an interconnection trench for an upper interconnection being thereby formed in the third and second insulating layers. When a resist mask is used for formation of the via hole, since the thickness of the resist mask can be made larger than the depth of the upper trench, the resist mask has no large step along the edges of the upper trench.

### BACKGROUND OF THE INVENTION

1. Field of the Invention

The present invention relates to a method of manufacturing a semiconductor device, or more particularly, to a method of manufacturing a semiconductor device including a dual-damascene process of forming an interconnection and a via plug concurrently.

2. Description of a Related Art

Along with the trend to employment of microscopic and multilayer interconnections in semiconductor devices, damascene process instead of ordinary lithography is often adopted for a interconnection forming step. The damascene process is such that a trench is formed in an interlayer insulating layer, and a interconnection material is embedded in the trench and evened through chemical mechanical polishing (CMP).

Recently, an interconnection forming step referred to as a dual-damascene process has been discussed in efforts to simplify a complex step. At the dual-damascene process, an interconnection trench and a via hole are formed in advance, and a conductive material is embedded in the interconnection trench and the via hole concurrently. These days, various dual-damascene processes have been proposed.

A method of forming interconnection trenches and then forming via holes (referred to as a trench-first method) is categorized as one dual-damascene technique. FIG. 2 presents an example of the trench-first method as a related art of the present invention.

Lower-layer interconnection 201 composed of a barrier metal 202 and a copper (Cu) film 203 is formed in the surface of a first insulating layer 200 on a semiconductor substrate. A cap layer 204, a second insulating layer 205, a middle stopper film 206, and a third insulating layer 207 are successively formed on the insulating layer 200 and lower-layer interconnections 201. A first resist pattern is formed on the third insulating layer 207 and the third insulating layer 207 is etched using the first resist pattern as a mask, whereby an interconnection trench 210 is formed. Thereafter, a second resist pattern 211 is formed on the third insulating layer 207 and in the interconnection trench, and then the middle stopper film 206, second insulating layer 205, and cap layer 204 are etched using the second resist pattern as a mask. This results in a via hole (not shown). Thereafter, a metal film is formed in the interconnection trench and the via hole and on the third insulating layer 207. Chemical mechanical polishing (CMP) is performed in order to remove the metallic film on the third insulating layer 207. Thus, an interconnection and a via plug are formed concurrently (not shown).

However, the manufacturing method presented in FIG. 2 has a problem that the resist pattern 211 has an inadequate shape for forming the via hole as shown in FIG. 2. Especially in case the width of the interconnection trench 210 is relatively large and the depth thereof is larger than the thickness of a resist film, the resist film applied thereon has a large step along the edges of the trench 210. This leads to an uneven thickness of the resist film. Consequently, when the resist film having the uneven thickness is subjected to lithography, the shape of the complete resist pattern is unsatisfactorily. This makes it hard to form the via hole. For example, when a via hole is formed by using the resist pattern 211 as shown in FIG. 2, since the resist pattern 211 is a little etched during etching of the stopper film 206 and the second insulating layer 205, the edges of the third insulating layer 207 are exposed and eventually etched.

Particularly, in interconnection layer including a power line, which are generally formed on an upper layer in a multilayer interconnection structure, the width and thickness of the interconnection (depth of the interconnection trench) are made large in order to minimize resistance. Therefore, the above problem is likely to occur.

The above problem can be solved by making the thickness of the resist film larger than the depth of the interconnection trench. However, if the resist film is too thick, a resolution deteriorates. This is not preferred. Moreover, the width and depth of the interconnection trench depend on a required resistance value. Therefore, the width and depth of the interconnection trench cannot be changed despite the above problem.

### SUMMARY OF THE INVENTION

Accordingly, an object of the present invention is to provide a method of manufacturing a semiconductor device having a dual-damascene process capable of forming an interconnection trench and a via hole highly accurately.

According to the present invention, there is provided a method of manufacturing a semiconductor device, which comprises forming first, second, and third insulating layers over a lower interconnection; selectively etching a part of the third insulating layer to form an upper trench, which exposes an upper surface of the second insulating layer; forming via hole, of which diameter is smaller than the width of the upper trench, in the second and first insulating layers; and selectively etching the second insulating layer to form lower trench whose width is nearly identical to the width of the upper trench, an interconnection trench being thereby formed for an upper interconnection in the third and second insulating layers.

As mentioned above, according to the present invention, the interconnection trench is formed by two steps and the via hole is formed after formation of the upper trench before formation of the lower trench. Therefore, for example, when a resist film is used as the mask pattern, since the depth of the upper trench can be made smaller than the thickness of the resist, the resist has no large step along the edges of the upper trench and becomes even. Consequently, the mask pattern can have an adequate shape for being used as a mask. Eventually, the via hole can be formed reliably.

In other word, a feature of the present invention is that an insulating layer is selectively removed to form a first trench, a depressed portion, whose thickness is reduced, is thereby formed in the insulating layer, a via hole is formed in the depressed portion, and then the depressed portion is selectively removed further to form a second trench. Thus, the insulating layer can be formed by one deposition step.

### BRIEF DESCRIPTION OF THE DRAWINGS

The above and other objects, advantages and features of the present invention will be more apparent from the following description taken in conjunction with the accompanying drawings, in which:

FIG. 1A to FIG. 1J are sectional views presenting the steps of a semiconductor device manufacturing process in accordance with an embodiment of the present invention; and

FIG. 2 is a sectional view concerning a semiconductor device manufacturing process in accordance with a related art of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

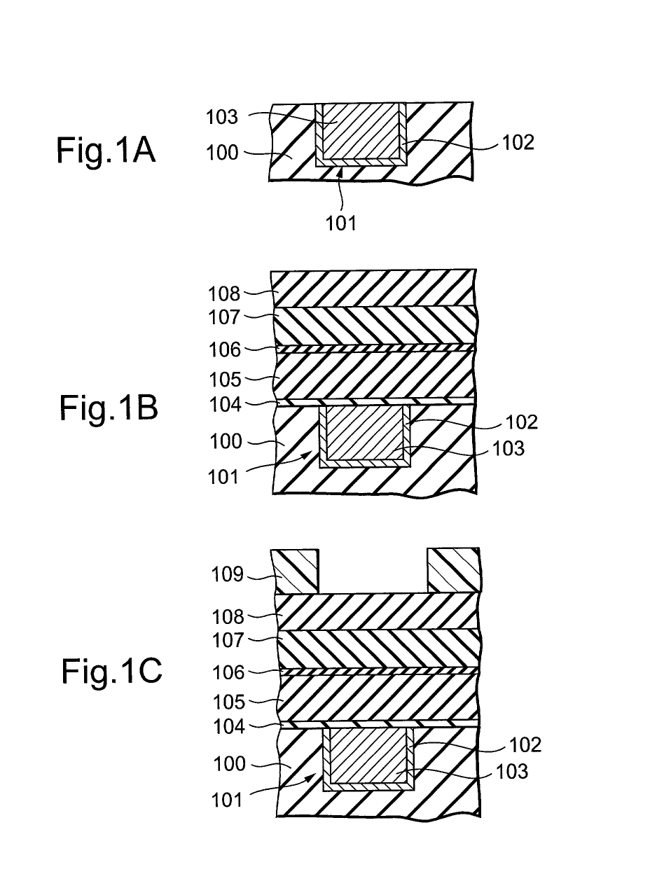

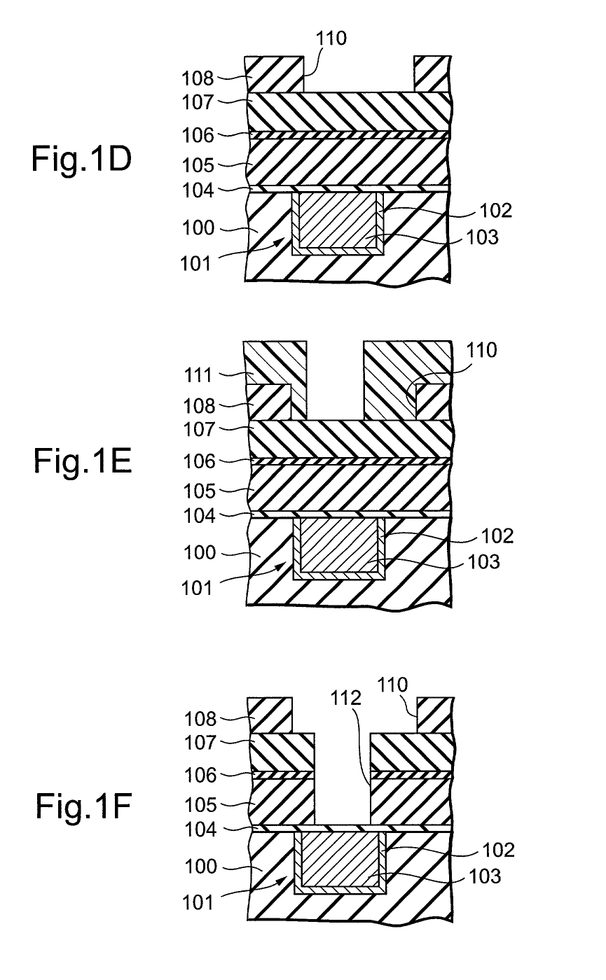

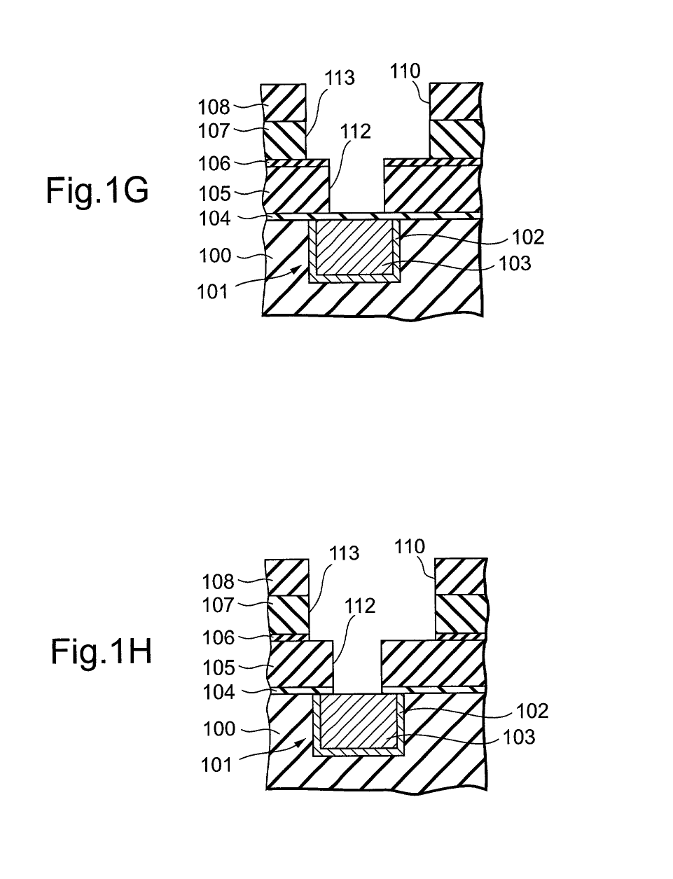

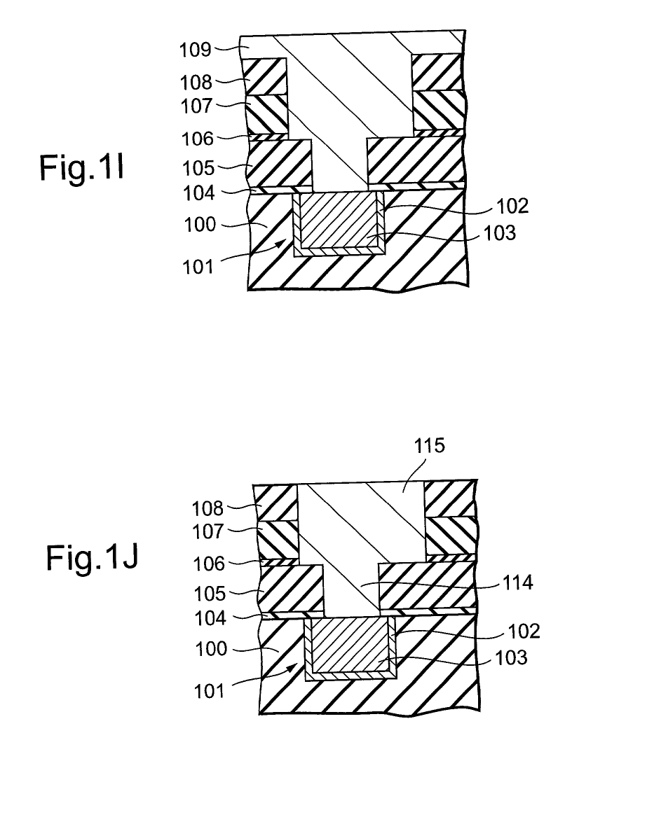

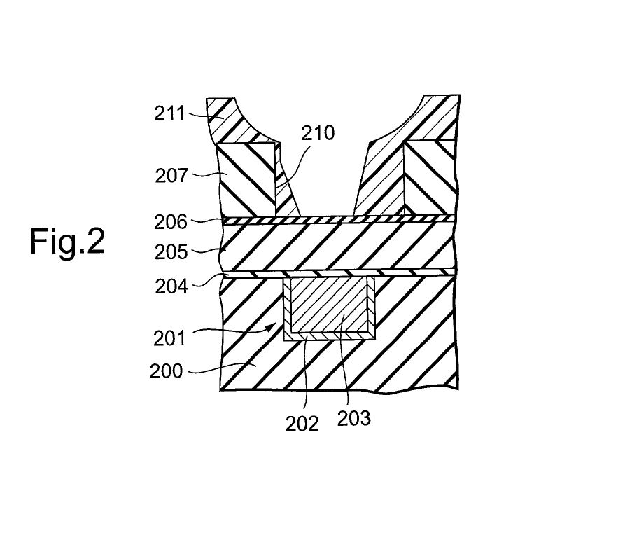

As shown in FIG. 1A, a barrier metal 102 made of TaN is layered inside trench formed in the surface of an insulating layer 100 coated over a semiconductor substrate (not shown). A copper film is formed in the trench, whereby a lower-layer interconnection 101 is formed.

Thereafter, as shown in FIG. 1B, a cap layer 104 made of a silicon nitride and having a thickness of 50 nm, a first insulating layer 105 made of a silicon oxide and having a thickness of 1000 nm, a middle stopper film 106 made of a silicon carbide and having a thickness of 50 nm, a second insulating layer 107 made of a silicon oxide and having a thickness of 500 nm, and a third insulating layer 108 made of a silicon carbide and having a thickness of 300 nm are formed successively on the insulating layer 100.

Thereafter, as shown in FIG. 1C, a resist pattern 109 having a opening whose width is equivalent to the width of upper-layer interconnection is formed by ordinary lithography.

Thereafter, as shown in FIG. 1D, the third insulating layer 108 is etched by performing anisotropic dry etching using the resist pattern 109 as a mask to expose the surface of the second insulating layer 107 and to form an upper trench 110. As mentioned above, the second insulating layer 107 is made of a silicon oxide and the third insulating layer 108 is made of a silicon carbide. Therefore, when the third insulating layer 108 is etched at a higher etching rate than the second insulating layer 107, the upper trench 110 can be formed selectively in third insulating layer 108. Thereafter, the resist pattern 109 is removed.

Thereafter, as shown in FIG. 1E, a resist film is applied to the entire surface, and a resist pattern 111 for forming a via hole is then formed by performing ordinary lithography. At this time, the depth of the upper trench 110, that is, the thickness of the third insulating layer 108 is set to a value smaller than the thickness of the resist film. Consequently, the resist film can be applied with an even thickness without any large step. Therefore, the resist pattern 111 can have an adequate shape for being used as a mask.

Thereafter, as shown in FIG. 1F, the second insulating layer 107, middle stopper film 106, and first insulating layer 105 are successively etched by using the resist pattern 111 as a mask to expose the surface of the cap layer 104 and to form the via hole 112. When the via holes 112 are formed, since the cap layer 104 is not etched, the lower-layer interconnections 101 are protected from being oxidized in the subsequent step of removing the photoresist 111.

Incidentally, the thickness of the third insulating layer 108 can be changed to a proper value so that it will be smaller than the thickness of the resist film. However, when the third insulating layer 108 is too thin, the second insulating layer 107 must be made so thick as to ensure a depth necessary for an interconnection trench. This leads to an increase in the depth of via hole to be formed through etching. This is not preferred because the etching for forming such a deep via hole is difficult. Consequently, the thickness of the third insulating layer is preferably made as large as possible within a range of values that are smaller than the thickness of the resist film.

After the photoresist 111 is removed, as shown in FIG. 1G, the second insulating layer 107 is selectively removed by performing anisotropic dry etching with using the third insulating layer 108 as a mask to form a lower trench 113. On the contrary to the steps shown in FIG. 1C and FIG. 1D for forming the upper trench portions 110, the second insulating layer 107 is etched at a higher etching rate than the third insulating layer 108 in this forming step of the lower trench 113. Thus, the lower trench portions 113 can be selectively formed using the third insulating layer 108 as a mask. At this time, since the middle stopper film 106 is made of the silicon carbide which is the same material as the third insulating layer 108, the middle stopper film 106 acts as an etching stopper. Consequently, the middle stopper film 106 is bared and left as the bottoms of the lower trench 113.

Thereafter, as shown in FIG. 1H, the cap layer 104 under the via hole 112 is selectively etched to expose the surface of the copper film 103. At this time, the middle stopper film 106 under the lower trench is also removed in this embodiment. However, the middle stopper film 106 may not be removed but may be left. Thus, the interconnection trench and the via hole are completed.

Thereafter, as shown in FIG. 11, a metal film, for example, a copper film 109 is formed in the interconnection trench and via hole 112 and on the third insulating layer 108.

Thereafter, as shown in FIG. 1J, the metal film 109 on the third insulating layer 108 is removed by performing chemical mechanical polishing (CMP). This results in a via plug 114 and an upper-layer interconnection 115. At this time, the upper part of the third insulating layer 108 is removed together with the metal film. It is preferable that the CMP is performed under the condition that 90% or more in thickness of the third insulating layer 108 are left.

As mentioned above, according to the embodiment of the present invention, the interconnection trench is not completed through one etching. After the upper trench is formed, the via hole is formed, and then the lower trench is formed to complete the interconnection trench. Therefore, since the resist film is applied to the insulating layer having the upper trench whose depth is sufficiently smal, the resist film can be applied evenly. Consequently, the resist pattern for forming the via hole can have an adequate shape for an etching mask. Eventually, the problem that the upper part of interconnection trench is etched during forming of via hole can be avoided.

In the aforesaid embodiment, the middle stopper film 106 is formed so that it will act as an etching stopper during creation of the lower trench 113. Alternatively, the first insulating layer 105 may be made of a material different from the material of the second insulating layer 107, and the middle stopper film may thus be omitted.

The cap layer 104 may also be omitted if there is no step at which the lower-layer interconnection is exposed to an oxidization atmosphere.

Moreover, the materials composing the second insulating layer 107 and third insulating layer 108 may be materials other than the aforesaid ones as long as the etching rate ratio between the first insulating layer 107 and the second insulating layer 108 can be made high.

Furthermore, an insulating layer formed by one deposition step may be used instead of the insulating layers 105 to 108.

It is apparent that the present invention is not limited to the above embodiments, but may be modified and changed without departing from the scope and spirit of the invention.

What is claimed is:

1. A method of manufacturing a semiconductor device comprising:
forming first, second, and third insulating layers over a lower interconnection;
selectively etching a part of said third insulating layer to form an upper trench, which exposes an upper surface of said second insulating layer;
forming a via hole, of which diameter is smaller than the width of said upper trench, in said second and first insulating layers; and
selectively etching said second insulating layer to form a lower trench whose width is nearly identical to the width of said upper trench, an interconnection trench for an upper interconnection being thereby formed in said third and second insulating layers.

2. The method as claimed in claim 1, wherein said second insulating layer and said third insulating layer are made of different materials.

3. The method as claimed in claim 1, wherein said second insulating layer is made of a silicon oxide and said third insulating layer is made of a silicon carbide.

4. The method as claimed in claim 1, further comprising forming a middle stopper film between said first insulating layer and said second insulating layer, wherein:
said via hole is formed by etching said second insulating layer, said middle stopper film, and said first insulating layer; and
said middle stopper film acts as an etching stopper during formation of said lower trench.

5. The method as claimed in claim 4, wherein said first insulating layer and said second insulating layer are made of a first material, and said third insulating layer and said middle stopper film are made of a second material different from said first material.

6. The method as claimed in claim 5, wherein said first material is a silicon oxide and said second material is a silicon carbide.

7. The method as claimed in claim 1, further comprising:
forming a metal film in said via hole and said interconnection trench and on said third insulating layer; and
removing said metal film on said third insulating layer by performing chemical mechanical polishing (CMP) to form said upper interconnection and a via plug.

8. The method as claimed in claim 7, wherein said CMP is performed under the condition that 90% or more in depth of said upper trench is left.

9. The method as claimed in claim 7, wherein said metal film is a copper film.

10. The method as claimed in claim 1, further comprising forming a cap layer between said lower interconnection and said first insulating layer, wherein:
said via hole exposes a part of said cap layer; and
said part of said cap layer and said middle stopper film under said lower trench are removed at one time after formation of said lower trench to expose said lower interconnection.

11. The method as claimed in claim 10, wherein said cap layer is made of a silicon nitride.

12. A method of manufacturing a semiconductor device comprising:
forming first, second, and third insulating layers over a lower interconnection;
selectively etching a part of said third insulating layer to form an upper trench which exposes said second insulating layer;
forming a resist pattern having an opening, of which diameter is smaller than the width of said upper trench and which is in said upper trench;
etching said second and first insulating layers by using said resist pattern as a mask to form a via hole over said lower interconnection; and
etching said second insulating layer by using said third insulating layer, which has said upper trench, as a mask to form a lower trench, an interconnection trench for an upper interconnection being thereby formed in said third and second insulating layers.

13. The method as claimed in claim 12, wherein the thickness of said resist pattern is larger than the depth of said upper trench.

14. The method as claimed in claim 13, wherein the depth of said interconnection trench is larger than the thickness of said resist pattern.

15. The method as claimed in claim 12, wherein said second insulating layer is made of a silicon oxide and said third insulating layer is made of a silicon carbide.

16. The method as claimed in claim 12, further comprising
forming a middle stopper film between said first insulating layer and said second insulating layer,
wherein said via hole is formed by etching said second insulating layer, said middle stopper film and said first insulating layer and said middle stopper film acts as an etching stopper during formation of said lower trench.

17. The method as claimed in claim 16, wherein said first insulating layer and said second insulating layer are made of a silicon oxide, and said third insulating layer and said middle stopper film are made of a silicon carbide.

18. A method of manufacturing a semiconductor device comprising:
selectively removing an insulating layer to form a first trench, a depressed portion being thereby formed in said insulating layer;
removing a part of said depressed portion to form a hole that penetrates through said depressed portion; and
selectively removing said depressed portion having said hole to forma second trench in said insulating layer, said second trench being smaller in depth than said hole.

19. The method as claimed in claim 18, wherein said method further comprises filling said first and second trenches and said hole with a conductive layer, said conductive layer thereby having a conductive line portion formed along said first and second trenches and a conductive plug portion formed in said hole.

20. The method as claimed in claim 19, wherein said second trench is formed substantially in alignment with said first trench.
